(19) United States
(12) Patent Application Publication
(10) Pub. No.: US 2013/0105985 A1
(43) Pub. Date: May 2, 2013

(54) SEMICONDUCTOR DEVICE

(71) Applicants: Junji TSURUOKA, Anjo (JP); Seiji YASUI, Nagoya (JP); Osamu YAMATO, Okazaki (JP); Takayuki MAEDA, Chiryu (JP)

(72) Inventors: Junji TSURUOKA, Anjo (JP); Seiji YASUI, Nagoya (JP); Osamu YAMATO, Okazaki (JP); Takayuki MAEDA, Chiryu (JP)

(21) Appl. No.: 13/646,074

(22) Filed: Oct. 5, 2012

(30) Foreign Application Priority Data
Nov. 1, 2011 (JP) 2011-240560

(51) Int. Cl. H01L 23/48

(52) U.S. Cl. 257/773; 257/E23.01

(57) ABSTRACT

A semiconductor device includes a connection terminal. The connection terminal includes two legs bonded via a filler material to a bonding target object that is a substrate or one semiconductor element placed on the substrate; and a joining portion connected to the two legs, extending between the two legs, and separated from the bonding target object.

INCORPORATION BY REFERENCE

The disclosure of Japanese Patent Application No. 2011-240560 filed on Nov. 1, 2011 including the specification, drawings and abstract is incorporated herein by reference in its entirety.

### BACKGROUND OF THE INVENTION

The present disclosure relates to semiconductor devices including connection terminals.

### DESCRIPTION OF THE RELATED ART

This type of semiconductor device is conventionally known in the art (see, e.g., Japanese Patent Application Publication No. 2010-103222 (JP 2010-103222 A)).

In this semiconductor device, connection terminals (terminal bases) are bonded to a substrate by soldering, and the substrate is connected to bus bars. The connection terminals have a C-shaped cross section.

A technique is also known in which through holes are formed in the connection terminals in order to improve reliability of soldering (see, e.g., Japanese Patent Application Publication No. 2005-228898 (JP 2005-228898 A)).

### SUMMARY OF THE INVENTION

In the case of bonding a connection terminal to a substrate, etc. by a filler material, it is desirable that the filler material such as solder melted by heating spread on the entire bonding portion, and the excess filler material do not gather in one region. If the filler material does not spread on the entire bonding portion or if the excess filler material gathers in one region, reliability of bonding of the connection terminal may be reduced due to tilting of the connection terminal, etc.

In the connection terminal having a C-shaped cross section as disclosed in JP 2010-103222 A, the excess filler material tends to gather at the corner of the connection terminal, whereby reliability of bonding of the connection terminal may be reduced due to tilting of the connection terminal, etc.

It is an object of the present disclosure to provide a semiconductor device capable of reducing tilting of a connection terminal that is bonded to a substrate, etc. via a filler material.

According to an aspect of the invention, a semiconductor device which includes a connection terminal and which is characterized in that the connection terminal includes: two legs bonded via a filler material to a bonding target object that is a substrate or one semiconductor element placed on the substrate; and a joining portion connected to the two legs, extending between the two legs, and being separated from the bonding target object is provided.

According to the aspect, it is possible to obtain the semiconductor device which is capable of reducing tilting of the connection terminal that is bonded to the substrate, etc. via the filler material.

### BRIEF DESCRIPTION OF THE DRAWINGS

FIG. 1 is a perspective view showing a main part of a semiconductor device 1 according to an embodiment;

FIG. 2 is a sectional view of the semiconductor device 1 taken along line A-A in FIG. 1;

FIG. 3 is a sectional view of the semiconductor device 1 taken along line B-B in FIG. 1;

FIG. 4 is a diagram showing another embodiment of a second connection terminal 140;

FIG. 5 is a diagram illustrating a problem that occurs when a connection terminal having a C-shaped cross section is used;

FIG. 6 is a perspective view showing an embodiment of the second connection terminal 140 having cutouts 142c;

FIGS. 7A and 7B show sectional views along two directions, showing the bonding portion between the second connection terminal 140 in FIG. 6 and a heat spreader 20;

FIG. 8 is a perspective view showing another embodiment of the second connection terminal 140 having the cutouts 142c; and

FIG. 9 is a perspective view showing still another embodiment of the second connection terminal 140 having the cutouts 142c.

### DETAILED DESCRIPTION OF THE EMBODIMENTS

Embodiments will be described below with reference to the accompanying drawings.

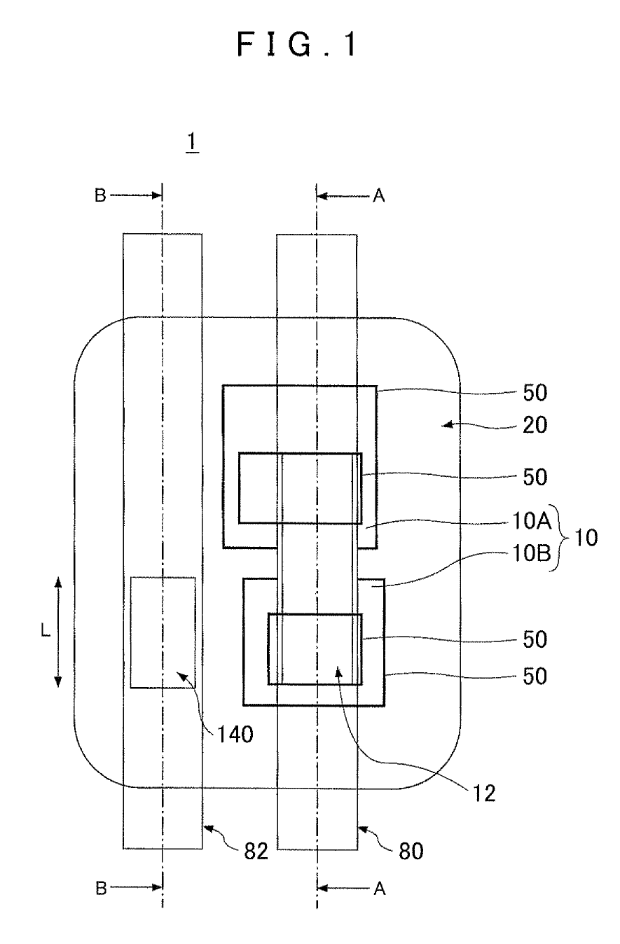

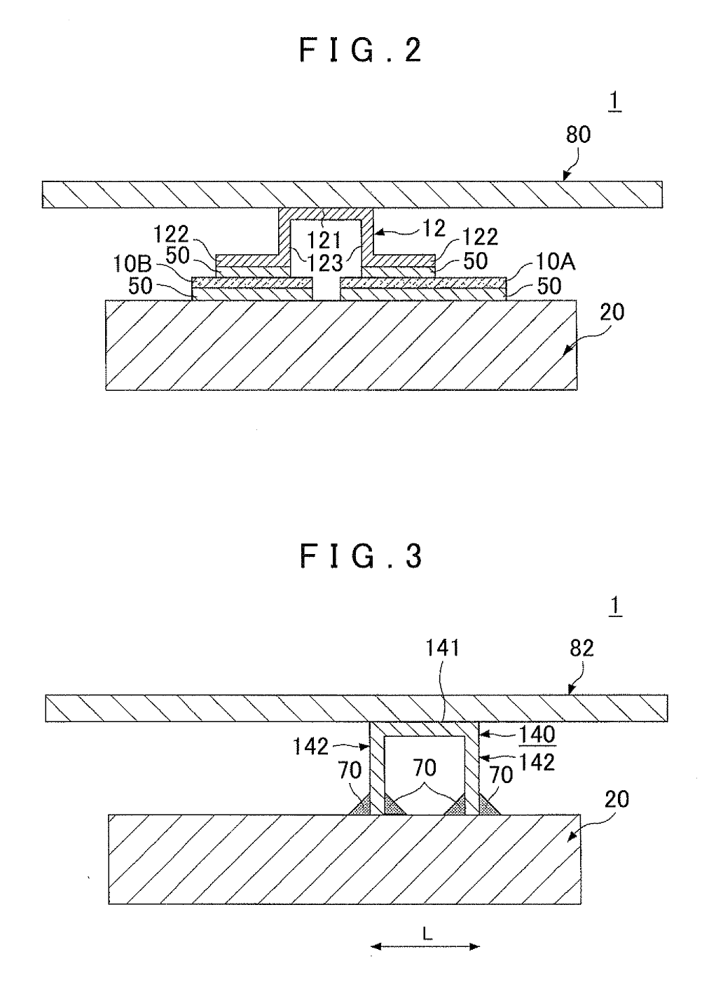

FIG. 1 is a perspective view showing a main part of a semiconductor device 1 according to an embodiment. FIG. 2 is a sectional view of the semiconductor device 1 taken along line A-A in FIG. 1. FIG. 3 is a sectional view of the semiconductor device 1 taken along line B-B in FIG. 1. In FIG. 1, a first external terminal 80 and a second external terminal 82 are shown transparent so that elements located below the first external terminal 80 and the second external terminal 82 can be seen. The vertical direction of the semiconductor device 1 varies depending on the state in which the semiconductor device 1 is mounted. In the following description, the upper side refers to the side of the semiconductor device 1 on which a semiconductor chip 10 is present with respect to a heat spreader 20. The semiconductor device 1 may form, e.g., an inverter for driving a motor, which is used in hybrid cars or electric cars.

As shown in FIGS. 1 and 2, the semiconductor device 1 includes the semiconductor chip 10, a first connection terminal 12, the heat spreader 20, and a second connection terminal 140.

The semiconductor chip 10 includes a power semiconductor element, and in this example, includes an insulated gate bipolar transistor (IGBT). The semiconductor chip 10 may include any type of power semiconductor element, and may include any number of power semiconductor elements. The semiconductor chip 10 may include other switching elements such as a metal oxide semiconductor field-effect transistor (MOSFET), instead of the IGBT. The semiconductor chip 10 is bonded to the heat spreader 20 by solder 50. In the illustrated example, the semiconductor chip 10 is comprised of a semiconductor chip 10A formed by an IGBT, and a semiconductor chip 10B formed by a free wheeling diode (FWD). In this case, the semiconductor chip 10A includes an emitter electrode at its upper surface, and a collector electrode at its lower surface. The semiconductor chip 10B includes an anode electrode at its upper surface, and a cathode electrode at its lower surface.

The first connection terminal 12 is fixed (bonded) to the electrodes of the semiconductor chips 10A, 10B by the solder 50. In the illustrated example, the first connection terminal 12 is bonded to the emitter electrode of the IGBT and the anode electrode of the FWD by the solder 50. As shown in FIG. 2, the first connection terminal 12 is shaped to protrude upward as viewed laterally, and is formed by an upper portion 121 separated upward from the upper surface of the heat spreader 20, two connection portions 122 extending at a height near the upper surface of the heat spreader 20, and a vertical leg portion 123 connecting the upper portion 121 and the two connection portions 122. The two connection portions 122 are bonded to the emitter electrode of the IGBT and the anode electrode of the FWD, respectively. As shown in FIGS. 1 and 2, the first external terminal 80 is bonded to the upper portion 121 of the first connection terminal 12 by, e.g., laser welding. The first external terminal 80 and the second external terminal 82 described below may be incorporated into the same bus bar module. In order to absorb vertical positional tolerance, the first external terminal 80 and the second external terminal 82 may have a cutout, etc. so as to be flexible.

The heat spreader 20 is a member that absorbs and diffuses heat generated by the semiconductor chip 10. The heat spreader 20 is made of a metal having a high thermal diffusion property, such as, e.g., copper or aluminum. In this example, the heat spreader 20 is made of copper as an example. A preferred example of copper is oxygen free copper (C1020) having the highest thermal conductivity among copper materials.

Although not shown in the figures, the heat spreader 20 may be bonded to a heat sink via an insulating layer. The insulating layer may be made of a resin adhesive or a resin sheet. The insulating layer may be made of, e.g., a resin containing alumina as a filler. The insulating layer is provided between the heat spreader 20 and the heat sink, and is bonded to the heat spreader 20 and the heat sink. The insulating layer ensures a high thermal conduction property from the heat spreader 20 to the heat sink while ensuring an electric insulation property between the heat spreader 20 and the heat sink. The heat sink is made of a highly thermally conductive material, and for example, is made of a metal such as aluminum. The heat sink includes fins on its lower surface. The heat sink may include any number of fins, and the fins may be arranged in any desired manner. The fins may be straight fins, or may be implemented by staggered arrangement of pin fins, etc. When the semiconductor device 1 is in a mounted state, the fins contact a cooling medium such as cooling water or cooling air. Thus, the heat that is generated by the semiconductor chip 10 during driving of the semiconductor device 1 is transferred from the fins of the heat sink to the cooling medium via the heat spreader 20 and the insulating layer, whereby cooling of the semiconductor device 1 is implemented.

The second connection terminal 140 is bonded to the upper surface of the heat spreader 20 by solder 70. As described above, the collector electrode of the IGBT as the semiconductor chip 10A (and the cathode electrode of the FWD as the semiconductor chip 10B) is connected to the heat spreader 20. Accordingly, the second connection terminal 140 forms an extraction portion of the collector electrode of the IGBT. As shown in FIGS. 1 and 3, the second connection terminal 140 is also bonded to the second external terminal 82 by, e.g., laser welding.

As shown in FIG. 3, the second connection terminal 140 is bonded at two points to the upper surface of the heat spreader 20. In the example shown in FIG. 3, the second connection terminal 140 includes two legs 142 extending in a direction perpendicular to the upper surface of the heat spreader 20, and a joining portion (an upper portion) 141 separated from the upper surface of the heat spreader 20 and extending parallel to the upper surface of the heat spreader 20. The joining portion 141 connects the two legs 142 together. That is, the second connection terminal 140 forms a downward facing C-shaped cross section by the two legs 142 and the joining portion 141.

The second connection terminal 140 is bonded to the heat spreader 20 by the solder 70 at the two legs 142. A plating layer having wettability with solder (solder wettability) may be formed on the second connection terminal 140. In this case, the plating layer may be formed only on a part of the second connection terminal 140 (e.g., only on the two legs 142).

The two legs 142 preferably have the same configuration. That is, the two legs 142 preferably have the same shape (length, width, height, etc.), and are arranged laterally symmetrically as viewed in cross section in FIG. 3. The second connection terminal 140 may be formed by performing press working on a linear plate material having a constant width.

The second connection terminal 140 may be mounted on the heat spreader 20 by, e.g., placing molten solder at two bonding positions on the upper surface of the heat spreader 20 and placing the legs 142 at the positions where the solder has been placed, respectively. At this time, the second connection terminal 140 may be oscillated in a predetermined scrubbing direction so as to allow the molten solder to spread on the entire bonding portion (that is, a scrubbing step may be performed). The predetermined scrubbing direction may be the direction connecting the two legs 142 (the direction L in FIG. 1).

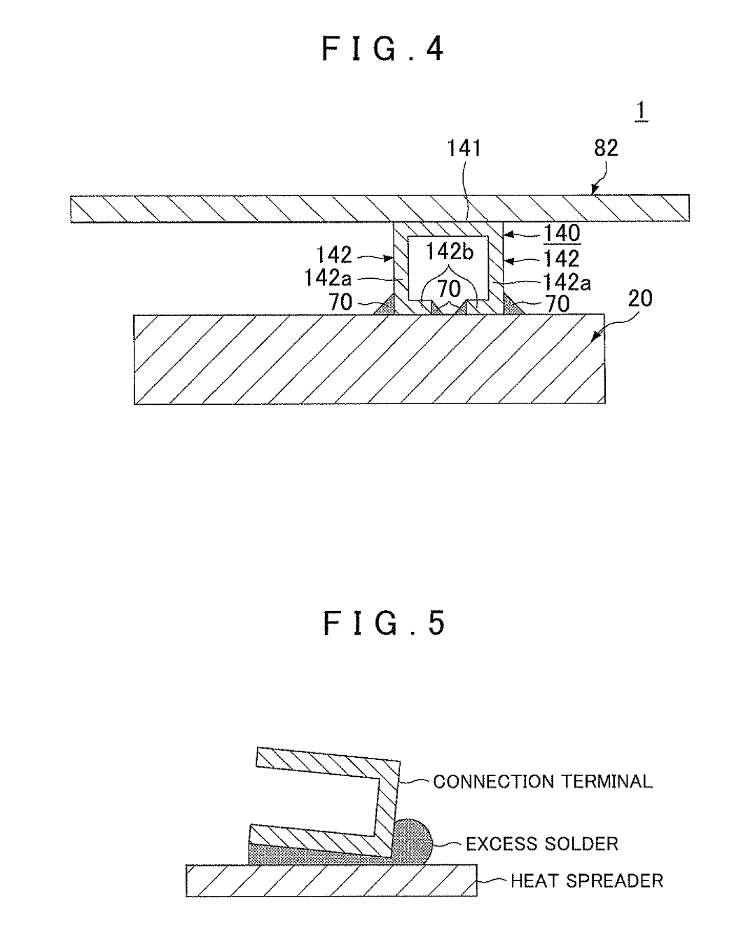

FIG. 4 is a diagram showing another embodiment of the second connection terminal 140, as viewed in cross section similar to that shown in FIG. 3.

In the example shown in FIG. 4, each of the two legs 142 includes a first portion 142a extending in the direction perpendicular to the upper surface of the heat spreader 20, and a second portion 142b bent from the first portion 142a to extend along the upper surface of the heat spreader 20. In this case as well, the second connection terminal 140 is similarly bonded at the two legs 142 to the heat spreader 20 by the solder 70.

In the example shown in FIG. 4, the second portions 142b of the two legs 142 extend in a direction toward each other. However, as still further embodiment, the second portions 142b of the two legs 142 may extend in a direction away from each other. Alternatively, one of the second portions 142b of the two legs 142 may extend in a direction toward the other second portion 142b, and the other second portion 142b may extend in a direction away from the one second portion 142b.

According to the present embodiment described above, as described above, the second connection terminal 140 is bonded at the two points (that is, the two legs 142) to the upper surface of the heat spreader 20 by the solder 70. Accordingly, the imbalance of the bonding portion due to the solder 70 is reduced in the direction connecting the two legs 142 (the direction L), whereby a disadvantage that is caused when a connection terminal having a C-shaped cross section (that is, a disadvantage such as that excess solder tends to gather at the corner of the connection terminal and the connection terminal is tilted, as shown in FIG. 5) is used can be prevented. This can enhance reliability of bonding between the second connection terminal 140 and the heat spreader 20.

The second connection terminal 140 preferably has a cutout that receives the solder 70. Such a cutout may be formed in any shape at any position in the leg 142. This allows excess solder to enter the cutout, and can prevent the excess solder from spreading out in an undesirable manner. Some preferred embodiments of the second connection terminal 140 having a cutout will be described below.

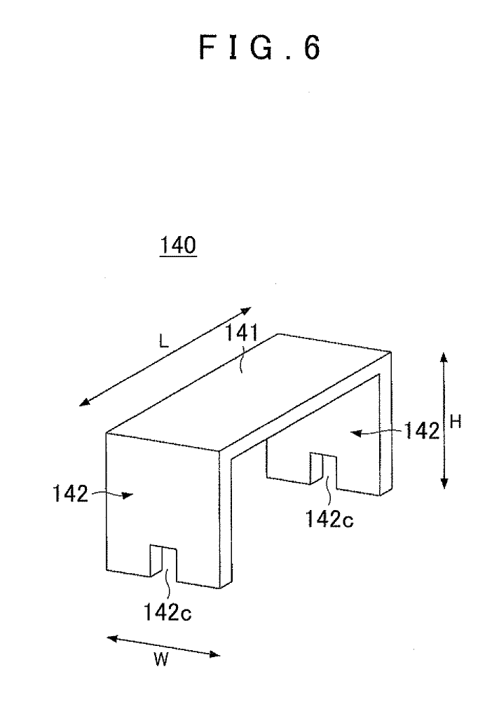

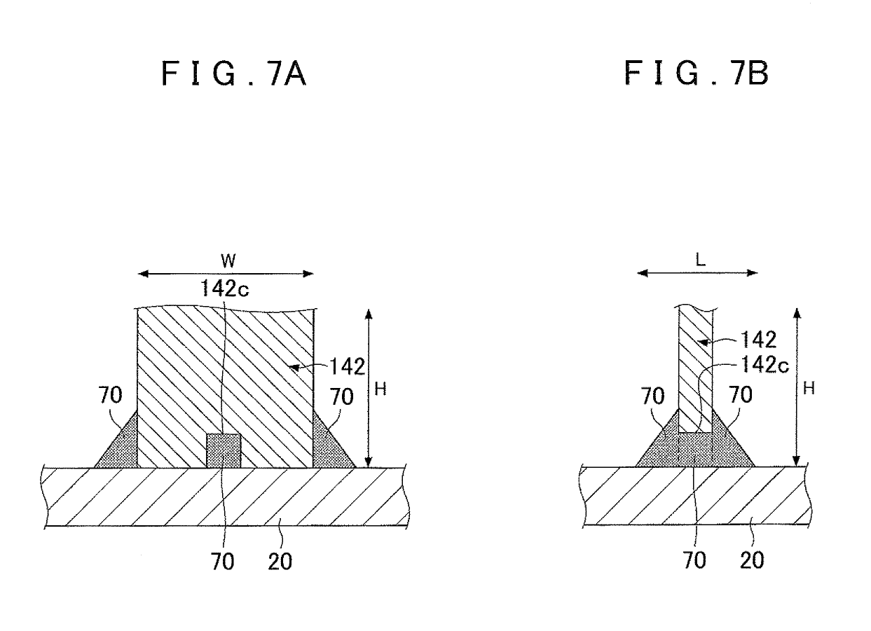

FIG. 6 is a perspective view showing an embodiment of the second connection terminal 140 having cutouts 142c. FIGS. 7A and 7B show sectional views along two directions, showing the bonding portion between the second connection terminal 140 and the heat spreader 20 (sectional views along the cutout 142c as viewed in directions L and W in FIG. 6). In the following description, the “direction L” corresponds to the direction connecting the two legs 142, and refers to the longitudinal second connection terminal 140, the “direction H” refers to the height direction, and the “direction W” refers to the lateral direction of the leg 142 (the direction perpendicular to the longitudinal direction and the height direction).

In the example shown in FIG. 6, each of the two legs 142 has the cutout 142c extending in the height direction H. As shown in FIGS. 7A and 7B, the cutout 142c receives the solder 70 in the bonding process. As shown in FIG. 6, the cutout 142c is preferably formed substantially in a central portion of the leg 142 in the lateral direction W. The cutouts 142c of the two legs 142 preferably have the same configuration (position, shape, etc.). In the example shown in FIG. 6, the cutout 142c is formed in the central portion of the leg 142 in the lateral direction W, and opens only at an edge of the leg 142 which is located on the heat spreader 20 side (a lower edge in the height direction H) of the leg 142. Since the cutout 142c thus forms a surrounded space, the molten solder 70 can also move (flow upward) into the cutout 142c extending in the height direction H. However, the cutout 142c may open at both the edge on the heat spreader 20 side of the leg 142 and one edge of the leg 142 in the lateral direction W (that is, the cutout 142c may be formed in an end of the leg 142 in the lateral direction W). A plurality of cutouts 142c may be formed in each leg 142. The cutout 142c may have any shape, and the shape of the cutout 142c may include a triangular shape, a circular shape, an oval shape, etc. in addition to the rectangular shape shown in the figures.

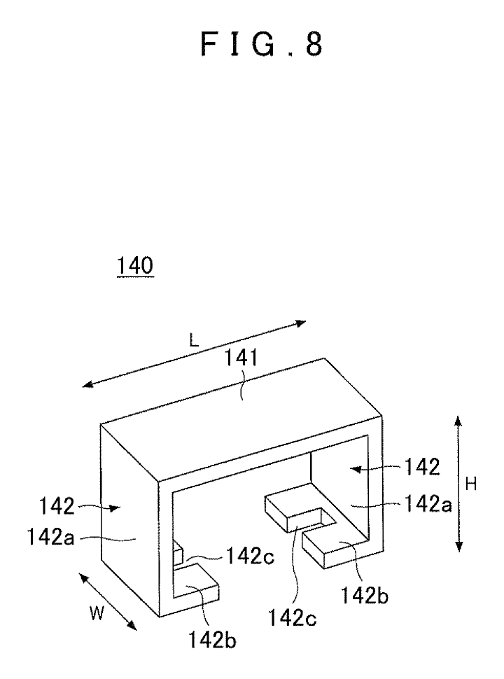

FIG. 8 is a perspective view showing another embodiment of the second connection terminal 140 having the cutouts 142c.

In the example shown in FIG. 8, as in the example shown in FIG. 4, each of the two legs 142 includes a first portion 142a extending in the direction perpendicular to the upper surface of the heat spreader 20, and a second portion 142b bent from the first portion 142a to extend along the upper surface of the heat spreader 20, and the cutout 142c is formed in the second portion 142b. Accordingly, in the example shown in FIG. 8, the cutout 142c extends in the longitudinal direction L. As shown in FIG. 8, the cutout 142c is similarly formed substantially in the central portion of the leg 142 in the lateral direction W. The cutouts 142c of the two legs 142 preferably have the same configuration (position, shape, etc.). In the example shown in FIG. 8, the cutout 142c is formed in the central portion of the leg 142 in the lateral direction W, and opens only at an edge of the leg 142 in the longitudinal direction L. However, the cutout 142c may open at both the edge of the leg 142 in the longitudinal direction L and one edge of the leg 142 in the lateral direction W, or may open only at one edge of the leg 142 in the lateral direction W. A plurality of cutouts 142c may be formed in each leg 142. The cutout 142c may have any shape, and the shape of the cutout 142c may include a triangular shape, a circular shape, an oval shape, etc. in addition to the rectangular shape shown in the figure.

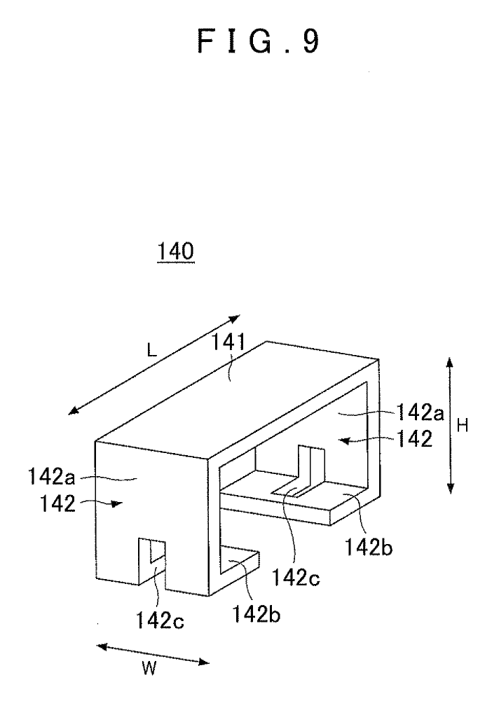

FIG. 9 is a perspective view showing still another embodiment of the second connection terminal 140 having the cutouts 142c.

In the example shown in FIG. 9, as in the example shown in FIG. 4, each of the two legs 142 includes a first portion 142a extending in the direction perpendicular to the upper surface of the heat spreader 20, and a second portion 142b bent from the first portion 142a to extend along the upper surface of the heat spreader 20, and the cutout 142c is formed to extend both in the first portion 142a and the second portion 142b. That is, the cutout 142c is formed in a region including the bent portion between the first portion 142a and the second portion 142b. Accordingly, in the example shown in FIG. 9, the cutout 142c extends in the height direction H in the first portion 142a and extends in the longitudinal direction L in the second portion 142b. As shown in FIG. 9, the cutout 142c is similarly formed substantially in the central portion of the leg 142 in the lateral direction W. The cutouts 142c of the two legs 142 preferably have the same configuration (position, shape, etc.). Similarly, a plurality of cutouts 142c may be formed in each leg 142. The cutout 142c may have any shape, and the shape of the cutout 142c may include a triangular shape, a circular shape, an oval shape, etc. in addition to the rectangular shape shown in the figure.

In the example shown in FIG. 9, the cutout 142c is formed in the central portion of the leg 142 in the lateral direction W, and is in the form of a hole surrounded along the entire perimeter thereof. However, the cutout 142c may further extend in the longitudinal direction L in the second portion 142b so as to open only at the edge of the leg 142 in the longitudinal direction L. Alternatively, the cutout 142c may open only at one edge of the leg 142 in the lateral direction W, or may open at both the edge of the leg 142 in the longitudinal direction L and one edge of the leg 142 in the lateral direction W.

The preferred embodiments of the present invention are described in detail above. However, the present invention is not limited to the above embodiments, and various modifications and substitutions can be made to the above embodiments without departing from the spirit and scope of the present invention.

For example, although the configuration of the second connection terminal 140 connecting the heat spreader 20 to the second external terminal 82 is particularly mentioned in the above description, connection between other parts can be implemented by using a connection terminal having a configuration similar to that of the second connection terminal 140. For example, instead of the first connection terminal 12, the semiconductor chip 10A may be connected to the first external terminal 80 by using a connection terminal having a configuration similar to that of the second connection terminal 140, and the semiconductor chip 10B may be connected to the first external terminal 80 by using a connection terminal having a configuration similar to that of the second connection terminal 140. In this case as well, each of the connection terminals having a configuration similar to that of the second connection terminal 140 is bonded at its two legs to the semiconductor chip 10A or the semiconductor chip 10B by solder.

Although the second external terminal 82 has a constant width in the above embodiments, the width of the second external terminal 82 may be varied. Although the leg 142 extends perpendicularly to the upper surface of the heat spreader 20 in the above embodiments, the leg 142 may extend at an angle other than the right angles to the upper surface of the heat spreader 20. For example, the leg 142 may include a first portion extending in an oblique direction with respect to the upper surface of the heat spreader 20, and a second portion bent from the first portion to extend along the upper surface of the heat spreader 20.

In the above embodiments, the semiconductor device 1 may include other configurations (e.g., at least one of elements of a DC-DC boost converter for driving a running motor), or may include other elements (a capacitor, a reactor, etc.) together with the semiconductor chips 10A, 10B. Although the semiconductor device 1 is herein applied to inverters for vehicles, the semiconductor device 1 may be used in inverters for other applications (trains, air conditioners, elevators, refrigerators, etc.). Moreover, the semiconductor device 1 may be used in devices other than the inverters, for example, in microprocessor units (MPUs) for computers and in high frequency power modules that are used in power amplifier circuits in transmitting portions of wireless communication devices.

In the above embodiments, the heat spreader 20 serves as a substrate on which the semiconductor chip 10 is placed and to which the second connection terminal 140 is bonded. However, the present invention is applicable to any other substrates. For example, the substrate on which the semiconductor chip 10 is placed and to which the second connection terminal 140 is bonded may be formed by a direct brazed aluminum (DBA) substrate, which is a highly thermally conductive ceramic substrate having an aluminum plate on both surfaces thereof, or a direct brazed copper substrate, which is a highly thermally conductive ceramic substrate having a copper plate on both surfaces thereof.

Although solder is used as the filler material in the above embodiments, various filler materials (e.g., filler materials containing gold, silver, copper; it doesn't matter if the filler material is a brazing filler material or a soldering filler material) may be used instead of solder. The filler material is not limited to the materials made of alloys, and any electrically conductive materials that are liquefied by heating and are solidified by cooling (including natural cooling) to implement bonding may be used as the filler material. Various kinds of solder may be used as the solder 70, regardless of the type of metal (e.g., tin) contained as a main component.

The configuration of the semiconductor device 1 is described with the single heat spreader 20 in the illustrated examples. However, the semiconductor device 1 may include any number of heat spreaders 20. For example, the semiconductor device 1 may include six heat spreaders 20. In this case, the semiconductor chips 10 on the six heat spreaders 20 may form upper arms and lower arms of U-phase, V-phase, and W-phase of inverters for driving a motor, respectively.

What is claimed is:

1. A semiconductor device comprising a connection terminal, wherein
the connection terminal includes
two legs bonded via a filler material to a bonding target object that is a substrate or one semiconductor element placed on the substrate, and
a joining portion connected to the two legs, and extending between the two legs and being separated from the bonding target object.

2. The semiconductor device according to claim 1, wherein
each of the two legs has a cutout that receives the filler material.

3. The semiconductor device according to claim 2, wherein
each of the two legs has a first portion extending in a direction perpendicular to a surface of the substrate, and the cutout is formed in the first portion.

4. The semiconductor device according to claim 3, wherein
the cutout is a closed cutout in a form of a hole, or is a cutout that opens at only one of edges of the leg in three directions.

5. The semiconductor device according to claim 4, wherein
each of the two legs includes a first portion extending in the direction perpendicular to the surface of the substrate, and a second portion bent from the first portion to extend in a direction parallel to the surface of the substrate.

6. The semiconductor device according to claim 5, wherein
the two legs have the same configuration.

7. The semiconductor device according to claim 1, wherein
each of the two legs includes a first portion extending in the direction perpendicular to the surface of the substrate, and a second portion bent from the first portion to extend in a direction parallel to the surface of the substrate.

8. The semiconductor device according to claim 7, wherein
the two legs have the same configuration.

9. The semiconductor device according to claim 1, wherein
the two legs have the same configuration.

10. The semiconductor device according to claim 2, wherein
each of the two legs includes a first portion extending in the direction perpendicular to the surface of the substrate, and a second portion bent from the first portion to extend in a direction parallel to the surface of the substrate

11. The semiconductor device according to claim 10, wherein
the two legs have the same configuration.

12. The semiconductor device according to claim 2, wherein
the two legs have the same configuration.

13. The semiconductor device according to claim 2, wherein
the cutout is a closed cutout in a form of a hole, or is a cutout that opens at only one of edges of the leg in three directions.

14. The semiconductor device according to claim 13, wherein
each of the two legs includes a first portion extending in the direction perpendicular to the surface of the substrate, and a second portion bent from the first portion to extend in a direction parallel to the surface of the substrate.

15. The semiconductor device according to claim 14, wherein
the two legs have the same configuration.

16. The semiconductor device according to claim 13, wherein
the two legs have the same configuration.

17. The semiconductor device according to claim 3, wherein
each of the two legs includes a first portion extending in the direction perpendicular to the surface of the substrate, and a second portion bent from the first portion to extend in a direction parallel to the surface of the substrate.

18. The semiconductor device according to claim 17, wherein
the two legs have the same configuration.

19. The semiconductor device according to claim 3, wherein
the two legs have the same configuration.

20. The semiconductor device according to claim 4, wherein
the two legs have the same configuration.
